(19) United States
(12) Patent Application Publication
(10) Pub. No.: US 2025/0351471 A1
(43) Pub. Date: Nov. 13, 2025

(54) Guard Ring Design For Through Via

(71) Applicant: Taiwan Semiconductor Manufacturing Company, Ltd., Hsin-Chu (TW)

(72) Inventors: Min-Feng Ku, Hsinchu City (TW); Yao-Chun Chuang, Hsinchu City (TW); Cheng-Chien Li, Hsinchu County (TW); Ching-Pin Lin, Hsinchu County (TW)

(21) Appl. No.: 19/277,929

(22) Filed: Jul. 23, 2025

Related U.S. Application Data
(62) Division of application No. 17/832,522, filed on Jun. 3, 2022.
(60) Provisional application No. 63/286,641, filed on Dec. 7, 2021.

(51) Int. Cl. H10D 62/10; H01L 21/768; H01L 23/48; H01L 23/522; H01L 23/528; H10D 84/01; H10D 84/03; H10D 84/83

(52) U.S. Cl. CPC H10D 62/102; H01L 21/76898; H01L 23/481; H01L 23/5226; H01L 23/5283; H10D 84/0149; H10D 84/038; H10D 84/83

(57) ABSTRACT

An exemplary semiconductor structure includes a device substrate having a first side and a second side. A dielectric layer is disposed over the first side of the device substrate. A through via extends along a first direction through the dielectric layer and through the device substrate from the first side to the second side. A guard ring is disposed in the dielectric layer and around the through via. The guard ring includes metal layers stacked along the first direction. The metal layers include first sidewalls and second sidewall. The first sidewalls form an inner sidewall of the guard ring. An overlap between the first sidewalls of the metal layers is less than about 10 nm. The overlap is along a second direction different than the first direction.

This is a divisional application of U.S. patent application Ser. No. 17/832,522, filed Jun. 3, 2022, which is a non-provisional application of and claims benefit of U.S. Provisional Patent Application Ser. No. 63/286,641, filed Dec. 7, 2021, the entire disclosures of which are incorporated herein by reference.

### BACKGROUND

The semiconductor integrated circuit (IC) industry has experienced rapid growth. Continuing advances in semiconductor manufacturing processes have resulted in integrated circuits (“ICs”) having semiconductor devices with finer features and/or higher degrees of integration. Functional density (i.e., the number of interconnected devices per IC chip area) has generally increased while feature size (i.e., the smallest component that can be created using a fabrication process) has decreased. This scaling-down process generally has generally provided benefits by increasing production efficiency and lowering associated costs.

Advanced IC packaging technologies have been developed to further reduce density and/or improve performance of ICs, which are incorporated into many electronic devices. For example, IC packaging has evolved, such that multiple ICs may be vertically stacked in so-called three-dimensional (“3D”) packages, or 2.5D packages (which use an interposer). Through via (also referred to as through-silicon via (TSV)) is one technique for electrically and/or physically connecting stacked ICs. Such techniques sometimes implement protective structures and/or shielding structures, such as guard rings, to improve TSV reliability and integrity. Design improvements in protective structures and/or shielding structures are needed.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1 is a fragmentary cross-sectional view of a semiconductor structure having an improved guard ring design for a through via (or vertically oriented conductive structure), in portion or entirety, according to various aspects of the present disclosure.

FIG. 2 is a fragmentary top view of the semiconductor structure of FIG. 1, in portion or entirety, according to various aspects of the present disclosure.

FIGS. 3A-3C, FIG. 4, FIGS. 5A-5C, and FIG. 6 are enlarged, cross-sectional views of portions of guard rings that can be implemented in the semiconductor structure of FIG. 1 and FIG. 2 according to various aspects of the present disclosure.

FIGS. 7A-7D are top views of guard rings, in portion or entirety, that can be implemented in the semiconductor structure of FIG. 1 and FIG. 2 according to various aspects of the present disclosure.

FIG. 8 is a fragmentary diagrammatic cross-sectional view of a semiconductor arrangement, in portion or entirety, that includes the semiconductor structure of FIG. 1 and FIG. 2, according to various aspects of the present disclosure.

FIGS. 9A-9I are fragmentary cross-sectional views of a workpiece, in portion or entirety, at various fabrication stages of forming a TSV and a corresponding guard ring according to various aspects of the present disclosure.

FIGS. 10A-10E are fragmentary cross-sectional views of a workpiece, in portion or entirety, at various fabrication stages of forming a trench for a TSV, which can be implemented at the fabrication stage of FIG. 9E, according to various aspects of the present disclosure.

FIG. 11 is a flow chart of a method, in portion or entirety, for fabricating a semiconductor structure, such as the semiconductor structure of FIG. 1 and FIG. 2, according to various aspects of the present disclosure.

FIG. 12 is a fragmentary diagrammatic cross-sectional view of a device substrate, in portion or entirety, that can be implemented in the semiconductor structure of FIG. 1 and FIG. 2 according to various aspects of the present disclosure.

### DETAILED DESCRIPTION

The present disclosure relates generally to integrated circuit (IC) packaging, and more particularly, to guard rings for through vias.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact and may also include embodiments in which additional features may be formed between the first feature and the second feature, such that the first feature and the second feature may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

Advanced IC packaging technologies have been developed to further reduce density and/or improve performance of integrated circuits (ICs), which are incorporated into many electronic devices. For example, IC packaging has evolved, such that multiple ICs may be vertically stacked in three-dimensional (“3D”) packages or 2.5D packages (e.g., packages that implement an interposer). Through via (also referred to as through-silicon via (TSV)) is one technique for electrically and/or physically connecting stacked ICs. For example, where a first chip is stacked vertically over a second chip, a TSV may be formed that extends vertically through the first chip to the second chip, where the TSV electrically and/or physically connects a first conductive structure (e.g., first wiring) of the first chip to a second conductive structure (e.g., second wiring) of the second chip. The TSV is a conductive structure, such as a copper structure, and may extend through an entirety of the first chip to the second chip.

A guard ring is often formed around the TSV to protect the TSV, improve TSV performance, improve TSV structural stability, shield and/or reduce TSV-induced noise that can negatively impact the first chip and/or the second chip, or combinations thereof. The guard ring may be formed when forming a back-end-of-line (BEOL) structure of the first chip, such as first wiring of the first chip. The first wiring may be disposed over and connected to a first device substrate of the first chip and facilitate operation and/or electrical communication of devices and/or structures of the first device substrate. The TSV may be formed after forming the BEOL structure, for example, by etching through a dielectric layer of the BEOL structure in an area defined by the guard ring and through the first device substrate to form a TSV trench that exposes the second chip and filling the TSV trench with a conductive material. The TSV trench may expose a BEOL structure of the second chip, which may be disposed over and connected to a second device substrate of the second chip and facilitate operation and/or electrical communication of devices and/or structures of the second device substrate.

The present disclosure proposes a guard ring design that optimizes a spacing between a guard ring and a TSV and optimizes overlap between adjacent metal layers of the guard ring, adjacent levels of the metal layers of the guard ring, adjacent groups of metal layers of the guard ring, or combinations thereof to reduce and/or eliminate defects that may arise during formation of the TSV. In some embodiments, a distance between a guard ring and a TSV is about 0.2 μm to about 0.5 μm. In some embodiments, a ratio of an inner diameter (or an inner width) of a guard ring to a diameter (or width) of a TSV is greater than zero and less than about two. In some embodiments, overlap between adjacent metal layers of a guard ring is less than about 10 nm. In some embodiments, overlap between adjacent levels of the metal layers of a guard ring is less than about 10 nm. In some embodiments, overlap between adjacent groups of metal layers of a guard ring is less than about 10 nm. In some embodiments, overlap decreases from a top to a bottom of a guard ring. For example, a guard ring can include a first group of metal layers, a second group of metal layers, and a third group of metal layers. The second group of metal layers is between the first group of metal layers and the third group of metal layers, the first group of metal layers is a topmost group of metal layers of the guard ring, and the third group of metal layers is a bottommost group of metal layers of the guard ring. Overlap between adjacent metal layers in the first group of metal layers is greater than overlap between adjacent metal layers in the second group of metal layers, which is greater than overlap between adjacent metal layers in the third group of metal layers. The first group of metal layers, the second group of metal layers, and third group of metal layers each include at least two metal layers. In some embodiments, the first group of metal layers form a portion of a BEOL structure having a first pitch, the second group of metal layers form a portion of the BEOL structure having a second pitch, and the third group of metal layers form a portion of the BEOL structure having a third pitch. The first pitch, the second pitch, and the third pitch are different. Details of the proposed guard ring design and/or fabrication thereof are described herein. Different embodiments may have different advantages, and no particular advantage is required of any embodiment.

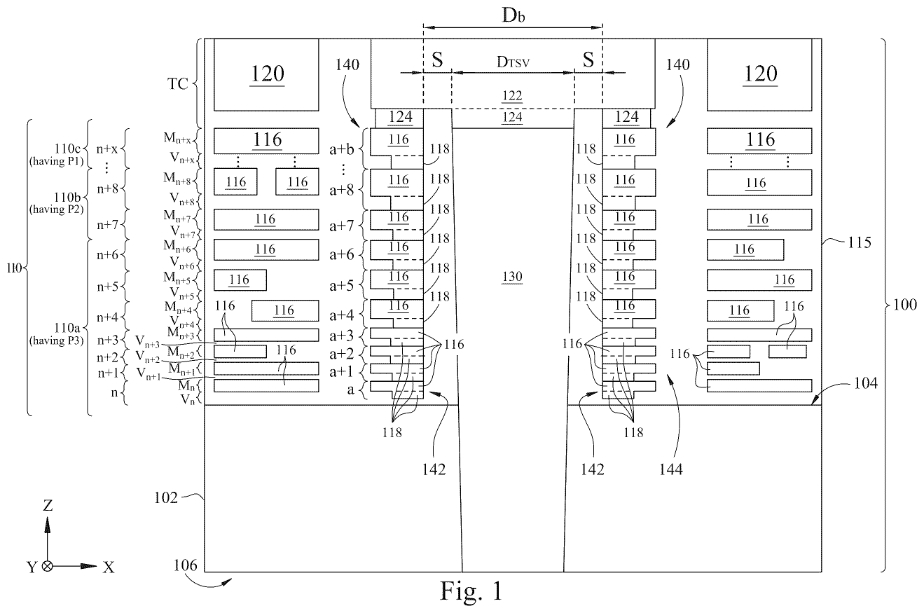

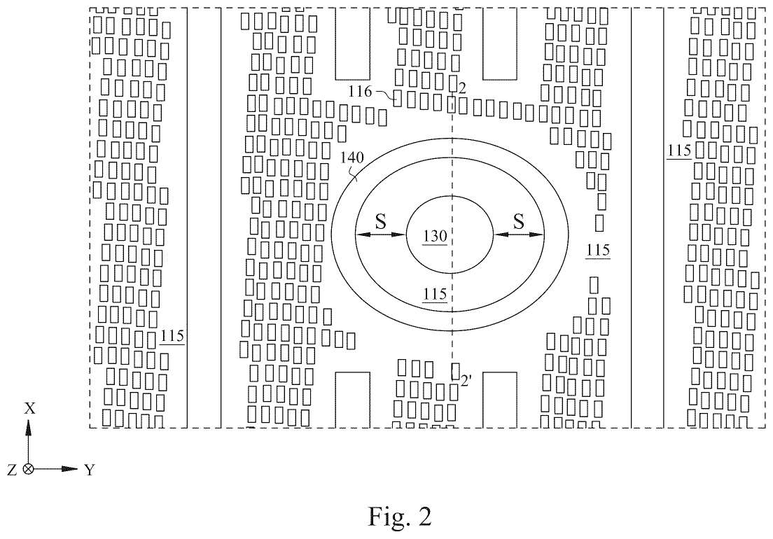

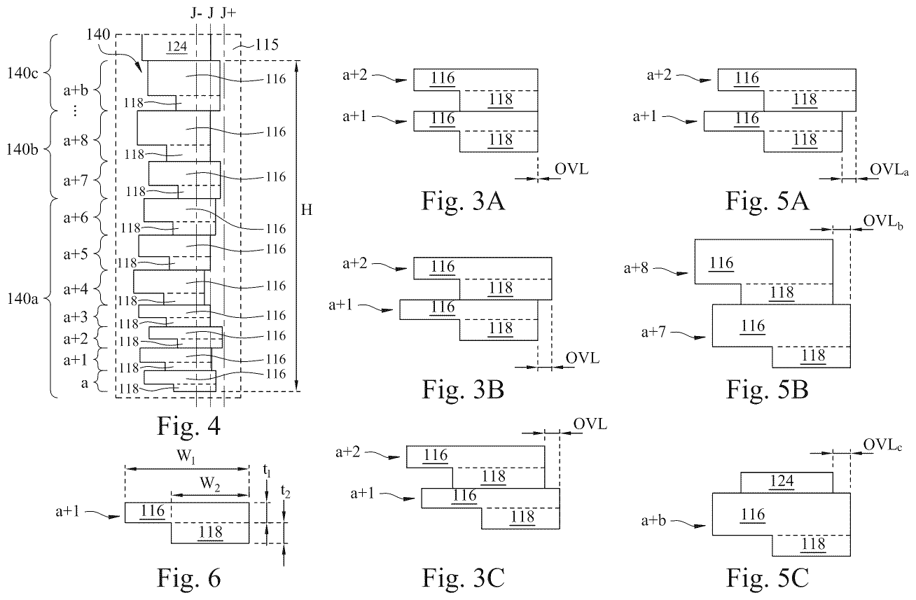

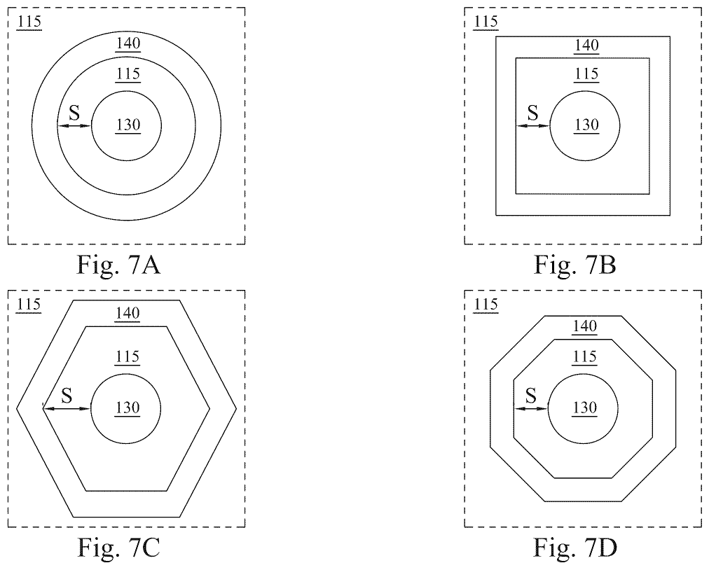

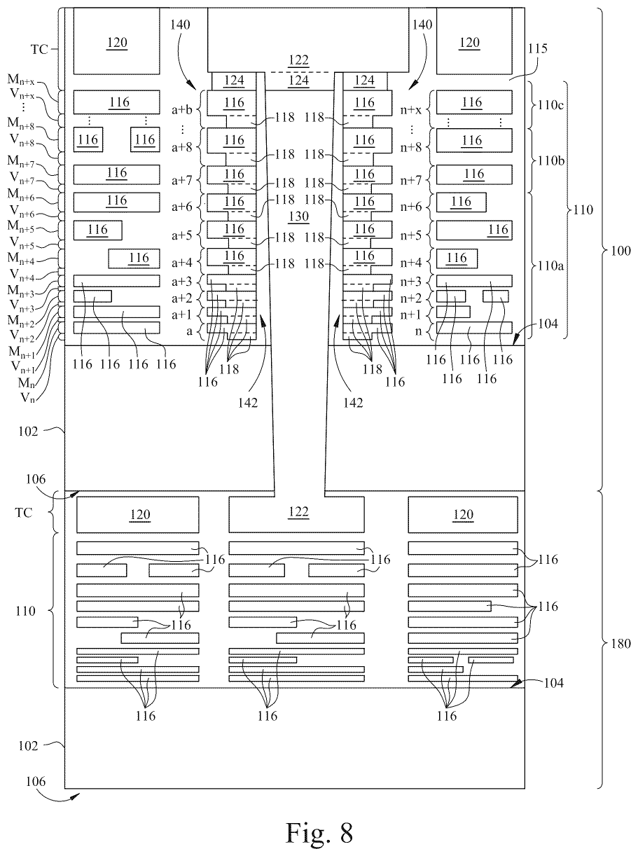

FIG. 1 is a fragmentary cross-sectional view of a semiconductor structure 100 having an improved guard ring design, in portion or entirety, according to various aspects of the present disclosure. FIG. 2 is a fragmentary top view of semiconductor structure 100 having the improved guard ring design, in portion or entirety, according to various aspects of the present disclosure. The cross-sectional view of FIG. 1 is along line 2-2′ of FIG. 2, and a top contact layer TC of semiconductor structure 100 depicted in FIG. 1 is removed in FIG. 2. FIGS. 3A-3C, FIG. 4, FIGS. 5A-5C, and FIG. 6 are enlarged, cross-sectional views of portions of guard rings that can be implemented in semiconductor structure 100 of FIG. 1 and FIG. 2 according to various aspects of the present disclosure. FIGS. 7A-7D are top views of guard rings, in portion or entirety, that can be implemented in semiconductor structure 100 of FIG. 1 and FIG. 2 according to various aspects of the present disclosure. FIG. 8 is a fragmentary diagrammatic cross-sectional view of a semiconductor arrangement, in portion or entirety, that includes semiconductor structure 100, according to various aspects of the present disclosure. FIG. 1, FIG. 2, FIGS. 3A-3C, FIG. 4, FIGS. 5A-5C, FIG. 6, FIGS. 7A-7D, and FIG. 8 are discussed concurrently herein for case of description and understanding. FIG. 1, FIG. 2, FIGS. 3A-3C, FIG. 4, FIGS. 5A-5C, FIG. 6, FIGS. 7A-7D, and FIG. 8 have been simplified for the sake of clarity to better understand the inventive concepts of the present disclosure. Additional features can be added in semiconductor structure, and some of the features described below can be replaced, modified, or eliminated in other embodiments of semiconductor structure.

In FIG. 1, a device substrate 102 is depicted having a side 104 (e.g., a frontside) and a side 106 (e.g., a backside) that is opposite side 104. Device substrate 102 can include circuitry (not shown) fabricated on and/or over side 104 by front end-of-line (FEOL) processing. For example, device substrate 102 can include various device components/features, such as a semiconductor substrate, doped wells (e.g., n-wells and/or p-wells), isolation features (e.g., shallow trench isolation (STI) structures and/or other suitable isolation structures), metal gates (e.g., a metal gate having a gate electrode and a gate dielectric), gate spacers along sidewalls of the metal gate, source/drain features (e.g., epitaxial source/drains), other suitable device components/features, or combinations thereof. In some embodiments, device substrate 102 includes a planar transistor, where a channel of the planar transistor is formed in the semiconductor substrate between respective source/drains and a respective metal gate is disposed on the channel (e.g., on a portion of the semiconductor substrate in which the channel is formed). In some embodiments, device substrate 102 includes a non-planar transistor having a channel formed in a semiconductor fin that extends from the semiconductor substrate and between respective source/drains on/in the semiconductor fin, where a respective metal gate is disposed on and wraps the channel of the semiconductor fin (i.e., the non-planar transistor is a fin-like field effect transistor (FinFET)). In some embodiments, device substrate 102 includes a non-planar transistor having channels formed in semiconductor layers suspended over the semiconductor substrate and extending between respective source/drains, where a respective metal gate is disposed on and surrounds the channels (i.e., the non-planar transistor is a gate-all-around (GAA) transistor). The various transistors of device substrate 102 can be configured as planar transistors or non-planar transistors depending on design requirements.

Device substrate 102 can include various passive microelectronic devices and active microelectronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide functionally distinct regions of an IC, such as a logic region (i.e., a core region), a memory region, an analog region, a peripheral region (e.g., an input/output (I/O) region), a dummy region, other suitable region, or combinations thereof. The logic region may be configured with standard cells, each of which can provide a logic device and/or a logic function, such as an inverter, an AND gate, an NAND gate, an OR gate, an NOR gate, a NOT gate, an XOR gate, an XNOR gate, other suitable logic device, or combinations thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or combinations thereof. In some embodiments, memory cells and/or logic cells include transistors and interconnect structures that combine to provide storage devices/functions and logic devices/functions, respectively.

A multi-layer interconnect (MLI) feature 110 is disposed over side 104 of device substrate 102. MLI feature 110 electrically connects various devices (e.g., transistors) and/or components of device substrate 102 and/or various devices (e.g., a memory device disposed within MLI feature 110) and/or components of MLI feature 110, such that the various devices and/or components can operate as specified by design requirements. MLI feature 110 includes a combination of dielectric layers and electrically conductive layers (e.g., patterned metal layers) configured to form interconnect (routing) structures. The conductive layers form vertical interconnect structures, such as device-level contacts and/or vias, and/or horizontal interconnect structures, such as conductive lines. Vertical interconnect structures typically connect horizontal interconnect structures in different layers/levels (or different planes) of MLI feature 110. During operation, the interconnect structures can route electrical signals between devices and/or components of device substrate 102 and/or MLI feature 110 and/or distribute electrical signals (for example, clock signals, voltage signals, and/or ground signals) to the devices and/or the device components of device substrate 102 and/or MLI feature 110. Though MLI feature 110 is depicted with a given number of dielectric layers and metal layers, the present disclosure contemplates MLI feature 110 having more or less dielectric layers and/or metal layers.

MLI feature 110 can include circuitry fabricated on and/or over side 104 by back end-of-line (BEOL) processing and thus can also be referred to as a BEOL structure. MLI feature 110 includes an n level interconnect layer, an (n+x) level interconnect layer, and intermediate interconnect layer(s) therebetween (i.e., an (n+1) level interconnect layer, an (n+2) level interconnect layer, and so on), where n is an integer greater than or equal to 1 and x is an integer greater than or equal to 1. Each of n level interconnect layer to (n+x) level interconnect layer includes a respective metallization layer and a respective via layer. For example, n level interconnect layer includes a respective n via layer (denoted as Vₙ) and a respective n metallization layer (denoted as Mₙ) over n via layer, (n+1) level interconnect layer includes a respective (n+1) via layer (denoted as Vₙ₊₁) and a respective (n+1) metallization layer (denoted as Mₙ₊₁) over (n+1) via layer, and so on for the intermediate layers to (n+x) level interconnect layer, which includes a respective (n+x) via layer (denoted as Vₙ₊ₓ) and an (n+x) metallization layer (denoted as Mₙ₊ₓ) over (n+x) via layer. In the depicted embodiment, n equals 1, x equals 9, and MLI feature 110 includes ten interconnect layers, such as a 1^{st} level interconnect layer including a V₁ layer and an M₁ layer, a 2^{nd} level interconnect layer including a V₂ layer and an M₂ layer, and so on to a 10^{th} level interconnect layer including a V₁₀ layer and an M₁₀ layer. Each via layer physically and/or electrically connects an underlying metallization layer and an overlying metallization layer, an underlying device-level contact layer (e.g., a middle end-of-line (MEOL) interconnect layer, such as an M₀ layer) and an overlying metallization layer, an underlying device feature (e.g., a gate electrode of a gate or a source/drain) and an overlying metallization layer, or an underlying metallization layer and an overlying top contact layer. For example, V₂ layer is between, physically connected, and electrically connected to M₁ layer and M₂ layer. In another example, V₁ layer is between, physically connected, and electrically connected to M₁ layer and an underlying device-level contact layer and/or an underlying device feature. In some embodiments, the metallization layers and the via layers are further electrically connected to device substrate 102. For example, a first combination of metallization layers and via layers are electrically connected to a gate of a transistor of device substrate 102 and a second combination of metallization layers and via layers are electrically connected to a source/drain of the transistor, such that voltages can be applied to the gate and/or the source/drain.

MLI feature 110 includes a dielectric layer 115 having metal lines 116, vias 118, other conductive features, or combinations thereof disposed therein. Each of Mₙ metallization layer to Mₙ₊ₓ metallization layer includes a patterned metal layer (i.e., a group of metal lines 116 arranged in a desired pattern) in a respective portion of dielectric layer 115. Each of Vₙ via layer to Vₙ₊ₓ via layer includes a patterned metal layer (i.e., a group of vias 118 arranged in a desired pattern) in a respective portion of dielectric layer 115. Dielectric layer 115 includes a dielectric material, such as silicon oxide, tetraethylorthosilicate (TEOS) oxide, phosphosilicate glass (PSG), boron-doped silicate glass (BSG), boron-doped PSG (BPSG), low-k dielectric material (having, for example, a dielectric constant that is less than a dielectric constant of silicon oxide (e.g., k<3.9)), other suitable dielectric material, or combinations thereof. Exemplary low-k dielectric materials include fluorosilicate glass (FSG), carbon-doped oxide, Black Diamond® (Applied Materials of Santa Clara, California), xerogel, aerogel, amorphous fluorinated carbon, parylene, benzocyclobutene (BCB), SiLK (Dow Chemical, Midland, Michigan), polyimide, other low-k dielectric material, or combinations thereof. In some embodiments, dielectric layer 115 includes a low-k dielectric material, such as carbon-doped oxide, or an extreme low-k dielectric material (e.g., k≤2.5), such as porous carbon-doped oxide.

Dielectric layer 115 can have a multilayer structure. For example, dielectric layer 115 includes at least one interlevel dielectric (ILD) layer, at least one contact etch stop layer (CESL) disposed between respective ILD layers, and at least one CESL disposed between a respective ILD layer and device substrate 102. In such embodiments, a material of the CESL is different than a material of the ILD layer. For example, where the ILD layer includes a low-k dielectric material, the CESL can include silicon and nitrogen (e.g., silicon nitride, silicon oxynitride, silicon carbonitride, or combinations thereof) or other suitable dielectric material. The ILD layer and/or the CESL may have a multilayer structure having multiple dielectric materials. In some embodiments, each of n level interconnect layer to (n+x) level interconnect layer includes a respective ILD layer and/or a respective CESL of dielectric layer 115, and respective metal lines 116 and vias 118 are in the respective ILD layer and/or the respective CESL. In some embodiments, each of Mₙ layer to Mₙ₊ₓ layer includes a respective ILD layer and/or a respective CESL of dielectric layer 115, where respective metal lines 116 are in the respective ILD layer and/or the respective CESL. In some embodiments, each of Vₙ layer to Vₙ₊ₓ layer includes a respective ILD layer and/or a respective CESL of dielectric layer 115, where respective vias 118 are in the respective ILD layer and/or the respective CESL.

A top contact (TC) layer is disposed over MLI feature 110, and in the depicted embodiment, are disposed over a topmost metallization layer of MLI feature 110 (i.e., M₁₀ layer). TC layer includes patterned metal layers (i.e., a group of contacts 120 and a contact 122 arranged in a desired pattern (e.g., a contact layer) and a group of vias 124 arranged in a desired pattern (e.g., a via layer)) in a respective portion of dielectric layer 115. The via layer (e.g., vias 124) physically and/or electrically connects the contact layer (e.g., contacts 120 and contact 122) to MLI feature 110 (e.g., metal lines 116 of Mₙ₊ₓ layer). Contacts 120 and/or contact 122 may facilitate electrical connection of MLI feature 110 and/or device substrate 102 to external circuitry and thus may be referred to as external contacts. In some embodiments, contacts 120 and/or contact 122 are under-bump metallization (UBM) structures. In some embodiments, dielectric layer 115 includes at least one passivation layer. For example, dielectric layer 115 may include a passivation layer disposed over a topmost metallization layer of MLI feature 110, such as M₁₀ layer. In such embodiments, TC layer may include the passivation layer, where contacts 120, contact 122, and vias 124 are disposed in the passivation layer. The passivation layer includes a material that is different than a dielectric material of an underlying ILD layer of MLI feature 110. In some embodiments, the passivation layer includes polyimide, undoped silicate glass (USG), silicon oxide, silicon nitride, other suitable passivation material, or combinations thereof. In some embodiments, a dielectric constant of a dielectric material of the passivation layer is greater than a dielectric constant of a topmost ILD layer of MLI feature 110. The passivation layer may have a multilayer structure having multiple dielectric materials. For example, the passivation layer can include a silicon nitride layer and a USG layer.

Metal lines 116, vias 118, contacts 120, contact 122, and vias 124 include a metal material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, metal lines 116, vias 118, contacts 120, contact 122, vias 124, or combinations thereof include a bulk metal layer (also referred to as a metal fill layer, a conductive plug, a metal plug, or combinations thereof). In some embodiments, metal lines 116, vias 118, contacts 120, contact 122, vias 124, or combinations thereof include a barrier layer, an adhesion layer, and/or other suitable layer disposed between the bulk metal layer and dielectric layer 115. The barrier layer can include titanium, titanium alloy (e.g., TiN), tantalum, tantalum alloy (e.g., TaN), other suitable barrier material (e.g., a material that can prevent diffusion of metal constituents from metal lines 116, vias 118, contacts 120, contact 122, vias 124, or combinations thereof into dielectric layer 115), or combinations thereof. In some embodiments, metal lines 116, vias 118, contacts 120, contact 122, vias 124, or combinations thereof include different metal materials. For example, lower metal lines 116 and/or vias 118 of MLI feature 110 include tungsten, ruthenium, cobalt, or combinations thereof, while higher metal lines 116 and/or vias 118 of MLI feature 100 include copper. In some embodiments, metal lines 116, vias 118, contacts 120, contact 122, vias 124, or combinations thereof include the same metal materials.

Each metallization layer is a patterned metal layer having metal lines 116, where the patterned metal layer has a corresponding pitch. Metallization layers of MLI feature 110 can thus be grouped by their respective pitches. A pitch of a patterned metal layer generally refers to a sum of a width of metal lines (e.g., metal lines 116) of the patterned metal layer and a spacing between directly adjacent metal lines of the patterned metal layer (i.e., a lateral distance between edges of directly adjacent metal lines 116 of the patterned metal layer). In some embodiments, a pitch of the patterned metal layer is a lateral distance between centers of directly adjacent metal lines 116 of the patterned metal layer. In FIG. 1, metallization layers having a same pitch are grouped together. For example, MLI feature 110 has a set 110a of metallization layers having a pitch P1, a set 110b of metallization layers having a pitch P2, and a set 110c of metallization layers having a pitch P3. Set 110a includes M₁ layer through M₇ layer, set 110b includes M₈ layer and M₉ layer, and set 110c includes M₁₀ layer. Pitch P1, pitch P2, and pitch P3 are different. In the depicted embodiment, pitch P1 is less than pitch P2, and pitch P2 is less than pitch P3. In such embodiments, pitch of metallization layers of MLI feature 110 increases as distance increases between the metallization layers and front side 104 of device substrate 102. In some embodiments, pitch P1 is greater than pitch P2, and pitch P2 is greater than pitch P3. In some embodiments, pitch P1 is greater than pitch P2 and less than pitch P3. In some embodiments, pitch P1 is less than pitch P2 and greater than pitch P3. MLI feature 110 can include any number of metallization layer sets (groups) having different pitches depending on IC technology node and/or IC generation (e.g., 20 nm, 5 nm, etc.). In some embodiments, MLI feature 110 includes three sets to six sets of metallization layers having different pitches.

A through substrate via (TSV) 130 (also referred to as a through silicon via or a through semiconductor via) is disposed in dielectric layer 115. TSV 130 is physically and/or electrically connected to TC layer (e.g., a respective via 124 physically and electrically connects TSV to contact 122, which is connected to a guard ring 140). TSV 130 extends from contact 122, through dielectric layer 115, and through device substrate 102. In FIG. 1, TSV 130 extends from side 104 to side 106 of device substrate 102, such that TSV 130 extends entirely through device substrate 102. TSV 130 has a dimension D_{TSV}, such as a width or a diameter, along the x-direction. In FIG. 2 and FIG. 7A, TSV 130 has a circular shape in a top view and dimension D_{TSV} represents a diameter of TSV 130. In such embodiments, TSV 130 may be a cylindrical structure that extends through dielectric layer 115. TSV 130 may have different shapes in a top view, such as a square shape, a rhombus shape, a trapezoidal shape, a hexagonal shape, an octagonal shape, or other suitable shape. In some embodiments, dimension D_{TSV} is substantially the same along a thickness of TSV 130 (e.g., along the z-direction). In some embodiments, dimension D_{TSV} varies along the thickness. For example, TSV 130 has tapered sidewalls, such that dimension D_{TSV} decreases from a top of TSV 130 (interfacing with contact 122) to a bottom of TSV 130 (at side 106 of device substrate 102). In some embodiments, dimension D_{TSV} increases or decreases along the thickness but is substantially uniform along the thickness in device substrate 102, or vice versa. The present disclosure contemplates TSV 130 having any variation of dimension D_{TSV} along its thickness depending on sidewall configuration.

TSV 130 includes a conductive material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, TSV 130 includes a bulk metal layer (also referred to as a metal fill layer, a conductive plug, a metal plug, or combinations thereof) and a barrier layer, where the barrier layer is disposed between the bulk metal layer and dielectric layer 115. The barrier layer can include titanium, titanium alloy (e.g., TiN), tantalum, tantalum alloy (e.g., TaN), other suitable barrier material (e.g., a material that can prevent diffusion of metal constituents from TSV 130 into dielectric layer 115), or combinations thereof. In some embodiments, the bulk metal layer is a copper plug or a tungsten plug, and the barrier layer is a metal nitride layer (e.g., TaN layer or TiN layer). In some embodiments, the bulk metal layer includes a seed layer between the barrier layer and the metal plug. The seed layer can include copper, tungsten, other suitable metals (such as those described herein), alloys thereof, or combinations thereof. In some embodiments, TSV 130 includes a dielectric liner between the bulk metal layer or the barrier layer and dielectric layer 115. The dielectric liner includes silicon oxide, silicon nitride, other suitable dielectric material, or combinations thereof. The bulk metal layer, the barrier layer, the seed layer, the dielectric liner, or combinations thereof may have a multilayer structure. In some embodiments, TSV 130 includes polysilicon (e.g., the metal plug is a polysilicon plug).

Guard ring 140 is disposed in dielectric layer 115 and around TSV 130. Guard ring 140 extends through dielectric layer 115 from TC layer to side 104 of device substrate 102. Guard ring 140 is separated from TSV 130 by dielectric layer 115. Guard ring 140 has a dimension D_{b}, such as a width or a diameter, along the x-direction. From a top view (FIG. 2 and FIG. 7A), guard ring 140 is a circular ring around TSV 130, and guard ring 140 extends continuously around TSV 130. In such embodiments, dimension D_{b} represents an inner diameter of guard ring 140. In some embodiments, guard ring 140 has other shapes in a top view, such as those depicted in FIGS. 7B-7D. For example, guard ring 140 may be a square ring (FIG. 7B), a hexagonal ring (FIG. 7C), an octagonal ring (FIG. 7D), or other suitable shaped ring. In some embodiments, guard ring 140 is discontinuous (e.g., a circular ring formed from discrete segments).

Guard ring 140 is physically and/or electrically connected to TC layer (e.g., vias 124 physically and electrically connect guard ring 140 to contact 122). Guard ring 140 may be physically and/or electrically connected to device substrate 102. For example, an MEOL layer (i.e., device-level contacts and/or vias) can physically and/or electrically connect guard ring 140 to device substrate 102, such as to a doped region (e.g., an n-well and/or a p-well) in device substrate 102. In some embodiments, guard ring 140 is electrically connected to a voltage. In some embodiments, guard ring 140 is electrically connected to an electrical ground. In some embodiments, guard ring 140 is configured to electrically insulate TSV 130 from MLI feature 110, device substrate 102, other device features and/or device components, or combinations thereof. In some embodiments, guard ring 140 absorbs thermal stress and/or mechanical stress from, within, and/or around TSV 130. In some embodiments, guard ring 140 reduces thermal stress and/or mechanical stress from, within, and/or around TSV 130. Such stresses can result from TSV 130, device substrate 102, and/or dielectric layer 115 having different coefficients of thermal expansion (CTE). Such stresses may result during and/or after fabrication of TSV 130. In some embodiments, guard ring 140 reduces or eliminates cracks at an interface of TSV 130 and device substrate 102 (e.g., at metal/semiconductor interfaces), which may arise from the stresses described herein. In some embodiments, guard ring 140 provides structural support, integrity, reinforcement, or combinations thereof for TSV 130.

A ratio of dimension D_{b} to dimension D_{TSV} is configured to optimize a spacing S (also referred to as a distance) along the x-direction between guard ring 140 and TSV 130. In some embodiments, the ratio of dimension D_{b} to dimension D_{TSV} is greater than zero and less than about two (i.e., 2>D_{b}/D_{TSV}>0). A D_{b}/D_{TSV} ratio that is equal to zero provides a spacing S equal to zero (i.e., no spacing is between guard ring 140 and TSV 130, and guard ring 140 may be physically connected to TSV 130), which negates a purpose and/or a function of guard ring 140. For example, when guard ring 140 is merely an extension of TSV 130 (and forms a portion thereof), guard ring 140 cannot protect TSV 130 as intended. For example, guard ring 140 cannot provide electrical insulation; reduce or eliminate stress from, within, and/or around TSV 130; reduce or eliminate cracking; provide structural integrity; or combinations thereof. A D_{b}/D_{TSV} ratio that is greater than two provides a spacing between guard ring 140 and TSV 130 that is too large, and guard ring 140 cannot protect TSV 130 as intended. For example, when guard ring 140 is spaced too far from TSV 130, guard ring 140 cannot sufficiently absorb and/or reduce stresses from, within, and/or around TSV 130. Stresses may then concentrate on TSV 130, which can degrade performance and/or structural integrity of TSV 130. In some embodiments, spacing S is about 20 nm to about 50 nm. A spacing S that is greater than 50 nm is too large and prevents guard ring 140 from sufficiently protecting TSV 130 (e.g., guard ring 140 cannot adequately absorb and/or reduce stresses from, within, and/or around TSV 130). A spacing S that is less than 20 nm is too small and can result in a connection between guard ring 140 and TSV 130, which may destroy a shielding function of guard ring 140.

Guard ring 140 is fabricated in conjunction with MLI feature 110, and guard ring 140 may be considered a portion of MLI feature 110. For example, guard ring 140 includes a stack of interconnect structures, where the interconnect structures are vertically stacked along the z-direction (or along a thickness direction of TSV 130). Each interconnect structure includes a respective metal line 116 and a respective via 118. In FIG. 1, the stack of interconnect structures includes an a interconnect structure, an (a+b) interconnect structure, and intermediate interconnect structure(s) therebetween (i.e., an (a+1) interconnect structure, an (a+2) interconnect structure, and so on), where a is an integer greater than or equal to 1 and b is an integer greater than or equal to 1. In the depicted embodiment, a is equal to n (e.g., a=1), b is equal to z (e.g., b=9), and guard ring 140 has an interconnect structure that corresponds with each level interconnect layer of MLI feature 110. For example, a interconnect structure forms a conductive ring around TSV 130 in n level interconnect layer, (a+1) interconnect structure forms a conductive ring around TSV 130 in (n+1) level interconnect layer, and so on for the intermediate interconnect structures, and (a+b) interconnect structure forms a conductive ring around TSV 130 in (n+x) level interconnect layer. The present disclosure contemplates guard ring 140 having a number of interconnect structures that is more or less than a number of levels of interconnect layers of MLI feature 110. For example, guard ring 140 may extend from (n+x) level interconnect layer to (n+5) interconnect layer of MLI feature 110.

Overlap in guard ring 140 is controlled to optimize spacing S between guard ring 140 and TSV 130 and/or reduce and/or eliminate defects that may arise during fabrication of TSV 130. Overlap (overlay) generally refers to a distance one layer (or structure) is shifted laterally relative to another layer (or structure). For example, in FIGS. 3A-3C, an overlap OVL is between a first interconnect structure of guard ring 140 (e.g., (a+2) interconnect structure) and a second interconnect structure of guard ring 140 (e.g., (a+1) interconnect structure). In FIG. 3A, overlap OVL equals zero and a sidewall (edge) of the first interconnect structure is vertically aligned with a sidewall (edge) of the second interconnect structure. In FIG. 3B, overlap OVL is greater than zero and the sidewall of the first interconnect structure is shifted laterally a distance to the right relative to the sidewall of the second interconnect structure. In FIG. 3C, overlap OVL is greater than zero and the sidewall of the first interconnect structure is shifted laterally a distance to the left relative to the sidewall of the second interconnect structure. In some embodiments, overlap OVL is between sidewalls of metal lines 116. In some embodiments, overlap OVL is between sidewalls of vias 118. In some embodiments, for all interconnect structures of guard ring 140, a sidewall of its respective metal line 116 is vertically aligned with a sidewall of its respective via 118. In some embodiments, for at least one interconnect structure of guard ring 140, a sidewall of its respective metal line 116 is not vertically aligned with a sidewall of its respective via 118. In such embodiments, overlap may be controlled between metal lines 116 to optimize spacing S between guard ring 140 and TSV 130.

In FIG. 1, guard ring 140 has an inner sidewall 142 (i.e., sidewall of guard ring 140 that is closest to TSV 130) that extends along the z-direction and is formed by sidewalls of interconnect structures (i.e., sidewalls of metal lines 116 and/or sidewalls of vias 118) of guard ring 140 that are closest to TSV 130. Dimension Db is defined by inner sidewall 142, and spacing S is between inner sidewall 142 and TSV 130. Overlap OVL between interconnect structures of guard ring 140 and/or between metal lines 116 of guard ring 140 is configured to provide inner sidewall 142 with a substantially vertical profile. For example, overlap OVL is about 0 nm to about 10 nm. In some embodiments, overlap OVL between any two interconnect structures of guard ring 140 (e.g., between (a+2) interconnect structure and (a+1) interconnect structure) is less than about 10 nm. In some embodiments, overlap OVL between any two metal lines 116 of guard ring 140 is less than about 10 nm. In some embodiments, overlap OVL between any two vias 118 of guard ring 140 is less than about 10 nm. In some embodiments, overlap OVL is between directly adjacent interconnect structures, metal lines 116, or vias 118. In some embodiments, overlap OVL that is less than about 10 nm can optimize spacing S, dimension D_{b}, a ratio of D_{b}/D_{TSV}, or combinations thereof, such as described herein. In some embodiments, overlap OVL that is less than about 10 nm reduces and/or eliminates defects that may arise during fabrication of TSV 130, such as described below. Overlap OVL that is greater than 10 nm can result in physical and/or electrical breaks between interconnect structures of guard ring 140, metal lines 116 of guard ring 140, vias 118 of guard ring 140, or combinations thereof. For example, when overlaps greater than 10 nm are tolerated during fabrication, (a+2) interconnect structure may not land on (a+1) interconnect structure, such that (a+2) interconnect structure is not physically and/or electrically connected to (a+1) interconnect structure. In another example, when overlaps greater than 10 nm are tolerated during fabrication, metal lines 116 may not land on vias 118, such that metal lines 116 are not physically and/or electrically connected to vias 118. In another example, when overlaps greater than 10 nm are tolerated during fabrication, vias 118 may not land on metal lines 116, such that vias 118 are not physically and/or electrically connected to metal lines 116.

In FIG. 4, guard ring 140 has a height H, and a line J is an axis along the z-direction that represents a pre-defined, desired location of inner sidewall 142 of guard ring 140, such that dimension D_{b} of guard ring 140 is substantially equal to a pre-defined dimension D_{b}. To provide substantially vertical inner sidewall 142 (e.g., inner sidewall 142 extends substantially along line J), overlap OVL of interconnect structures and/or metal lines 116 of guard ring 140 (i.e., any lateral shift along the x-direction of sidewalls of interconnect structures and/or metal lines 116 forming guard ring 140) is less than about 10 nm, such as described above. In some embodiments, any lateral shift of inner sidewall 142 is less than about 10 nm. For example, a line J+ is an axis along the z-direction that represents a maximum allowable right shift of a location of inner sidewall 142 from line J, and a line J− is an axis along the z-direction that represents a maximum allowable left shift of a location of inner sidewall 142 from line J. Inner sidewall 142 is provided with a substantially vertical profile when a distance along the x-direction between line J and line J+ is less than about 10 nm and a distance along the x-direction between line J and line J− is less than about 10 nm. In some embodiments, distances greater than 10 nm result in spacing S being too large or too small, and guard ring 140 and/or TSV 130 may suffer from issues described herein that can degrade device performance and/or device reliability. In some embodiments, distances greater than 10 nm result in a ratio of dimension D_{b}/dimension D_{TSV} being too large or too small, and guard ring 140 and/or TSV 130 may suffer from issues described herein that can degrade device performance and/or device reliability. In some embodiments, distances greater than 10 nm result in interconnect structures, metal lines 116, and/or vias 118 of guard ring 140 that are not physically and/or electrically connected, and guard ring 140 and/or TSV 130 may suffer from issues described herein that can degrade device performance and/or device reliability.

In some embodiments, interconnect structures, metal lines 116, vias 118, or combinations thereof of guard ring 140 can be divided into groups, and each group can be assigned different overlay OVL tolerances, so long as each allowable overlay OVL tolerance is less than about 10 nm. In FIG. 4, interconnect structures of guard ring 140 are grouped based on a pitch of a metallization layer to which the interconnect structures belong. For example, guard ring 140 includes a set 140a of interconnect structures that correspond with set 110a of metallization layers having pitch P1, a set 140b of interconnect structures that correspond with set 110b of metallization layers having pitch P2, and a set 140c of interconnect structures that correspond with set 110c of metallization layers having pitch P3. Set 140a includes a interconnect structure through (a+6) interconnect structure, set 140b includes (a+7) interconnect structure and (a+8) interconnect structure, and set 140c includes (a+b) interconnect structure. Set 140a, set 140b, and set 140c have different overlaps. For example, in FIGS. 5A-5C, set 140a has an overlap OVLₐ, set 140b has an overlap OVL_{b}, and set 140c has an overlap OVL_{c}. Overlap OVLₐ, overlap OVL_{b}, and overlap OVL_{c} are each less than about 10 nm, but overlap OVLₐ, overlap OVL_{b}, and overlap OVL_{c} are different. In some embodiments, overlap OVL of guard ring 140 is configured to increase as a distance along the z-direction from side 104 of device substrate 102 increases (i.e., overlap decreases from a top to a bottom of guard ring 140). For example, OVLₐ less than overlap OVL_{b}, which is less than overlap OVL_{c} (i.e., overlap OVLₐ<overlap OVL_{b}<overlap OVL_{c} and overlap OVL_{c}≤10 nm).

In some embodiments, overlap OVLₐ is between any two interconnect structures and/or metal lines 116 of set 140a. In some embodiments, overlap OVLₐ is between directly adjacent interconnect structures and/or metal lines 116 of set 140a. In some embodiments, overlap OVLₐ is between a bottommost interconnect structure of set 140a (e.g., a interconnect structure) and/or metal line 116 thereof and a contact and/or a via of an underlying MEOL layer. In some embodiments, overlap OVLₐ is between a topmost interconnect structure of set 140a (e.g., (a+6) interconnect structure) and/or metal line 116 thereof and a bottommost interconnect structure of set 140b (e.g., (a+7) interconnect structure) and/or metal line 116 thereof. In some embodiments, overlap OVL_{b} is between any two interconnect structures and/or metal lines 116 of set 140b. In some embodiments, overlap OVL_{b} is between directly adjacent interconnect structures and/or metal lines 116 of set 140b. In some embodiments, overlap OVL_{b} is between a bottommost interconnect structure of set 140b (e.g., (a+7) interconnect structure) and/or metal line 116 thereof and a topmost interconnect structure of set 140a (e.g., (a+6) interconnect structure) and/or metal line 116 thereof. In some embodiments, overlap OVL_{b} is between a topmost interconnect structure of set 140b (e.g., (a+8) interconnect structure) and/or metal line 116 thereof and a bottommost interconnect structure of set 140c (e.g., (a+b) interconnect structure) and/or metal line 116 thereof. In some embodiments, overlap OVL_{c} is between any two interconnect structures and/or metal lines 116 of set 140c. In some embodiments, overlap OVL_{c} is between directly adjacent interconnect structures and/or metal lines 116 of set 140c. In some embodiments, overlap OVL_{c} is between a bottommost interconnect structure of set 140c (e.g., (a+b) interconnect structure) and/or metal line 116 thereof and a topmost interconnect structure of set 140b (e.g., (a+8) interconnect structure) and/or metal line 116 thereof. In some embodiments, overlap OVL_{c} is between a topmost interconnect structure of set 140c (e.g., (a+b) interconnect structure) and/or metal line 116 thereof and vias 124 of TC layer.

As noted above, each interconnect structure of guard ring 140 (e.g., (a+1) interconnect structure) has a respective metal line 116 and a respective via 118. In FIG. 6, metal lines 116 of interconnect structures of guard ring 140 have a width W₁ along the x-direction and a thickness t₁ along the z-direction, and vias 118 of interconnect structures of guard ring 140 have a width W₂ along the x-direction and a thickness t₂ along the z-direction. Width W₁ is greater than width W₂. A ratio of width W₁ to width W₂ is greater than one to provide interconnect structures with at least one sidewall where a sidewall of metal line 116 is not vertically aligned with a sidewall of via 118. Where ratio of width W₁ to width W₂ is equal to 1 (and thus width W₁ equals width W₂), both sidewalls of metal line 116 are vertically aligned with sidewalls of via 118, which prevents adequate release of stress within, from, and/or around guard ring 140.

In some embodiments, metal lines 116 of guard ring 140 have the same width. In some embodiments, metal lines 116 of guard ring 140 have different widths (e.g., different widths W₁) and sidewalls of metal lines 116 forming inner sidewall 142 are substantially vertically aligned (i.e., overlap OVL is less than about 10 nm). In some embodiments, width of metal lines 116 of guard ring 140 increases along height H of guard ring 140 (i.e., as a distance from side 104 of device substrate 102 increases). For example, width W₁ of metal lines 116 increases from a first width to a second width. In such embodiments, width W₁ of metal line 116 of a interconnect structure may be equal to the first width, width W₁ of metal line 116 of (a+b) interconnect structure may be equal to the second width, and width W₁ of metal lines 116 of intermediate interconnect structures may be between the first width and the second width. In some embodiments, metal lines 116 of interconnect structures of a same set of guard ring 140 have the same width, but the sets have different widths and sidewalls of metal lines 116 forming inner sidewall 142 are substantially vertically aligned (i.e., overlap OVL is less than about 10 nm). For example, width W₁ of metal lines 116 of set 140a may be equal to a first width, width W₁ of metal lines 116 of set 140b may be equal to a second width, and width W₁ of metal lines 116 of set 140c may be equal to a third width, where the first width, the second width, and the third width are different. In some embodiments, the first width is greater than the second width, and the second width is greater than the third width. In some embodiments, metal lines 116 of interconnect structures of a same set of guard ring 140 have different widths, and sidewalls of metal lines 116 of the set forming inner sidewall 142 are substantially vertically aligned (i.e., overlap OVL is less than about 10 nm). For example, width W₁ of metal lines 116 of set 140a are different but TSV-facing sidewalls of metal lines 116 of set 140a have overlap OVLₐ.

In some embodiments, vias 118 of guard ring 140 have the same width. In some embodiments, vias 118 of guard ring 140 have different widths (e.g., different widths W₂) so long as sidewalls of metal lines 116 forming inner sidewall 142 are substantially vertically aligned (i.e., overlap OVL is less than about 10 nm). In such embodiments, sidewalls of metal lines 116 forming outer sidewall 144 of guard ring 140 may not be vertically aligned and/or may have overlay greater than 10 nm. In such embodiments, guard ring 140 may have a substantially vertical inner sidewall, but an outer sidewall having a non-uniform profile (e.g., stair profile, tapered profile, zig-zag profile, or other suitable profile). In some embodiments, width W₂ of vias 118 can vary as described above with reference to width W₁ of metal lines 116 (e.g., increase or decrease along height H, vary based on a set to which vias 118 belong, etc.). In some embodiments, thickness t₁ is greater than thickness t₂. In some embodiments, thickness t₁ is less than thickness t₂. In some embodiments, thickness t₁ is equal to thickness t₂. In some embodiments, metal lines 116 of guard ring 140 have the same thickness. In some embodiments, metal lines 116 of guard ring 140 have different thicknesses (e.g., different thicknesses t₁). In some embodiments, vias 118 of guard ring 140 have the same thickness. In some embodiments, vias 118 of guard ring 140 have different thicknesses (e.g., different thicknesses t₂). In some embodiments, thickness t₁ of metal lines 116 can vary as described above with references to width W₁ of metal lines 116 (e.g., increase or decrease along height H, vary based on a set to which metal lines 116 belong, etc.). In some embodiments, thickness t₂ of vias 118 can vary as described above with references to width W₁ of metal lines 116 (e.g., increase or decrease along height H, vary based on a set to which vias 118 belong, etc.).

In some embodiments, widths and/or thicknesses of metal lines 116 of guard ring 140 are different than widths and/or thicknesses, respectively, of metal lines 116 of the interconnect layers of MLI feature 110. In some embodiments, widths and/or thicknesses of vias 118 of guard ring 140 are different than widths and/or thicknesses, respectively, of vias 118 of the interconnect layers of MLI feature 110. In some embodiments, widths and/or thicknesses of metal lines 116 of guard ring 140 are the same as widths and/or thicknesses, respectively, of metal lines 116 of the interconnect layers of MLI feature 110. In some embodiments, widths and/or thicknesses of vias 118 of guard ring 140 are the same as widths and/or thicknesses, respectively, of vias 118 of the interconnect layers of MLI feature 110. In some embodiments, conductive materials of metal lines 116 and/or vias 118 of guard ring 140 are different than conductive materials of metal lines 116 and/or vias 118, respectively, of the interconnect layers of MLI feature 110. In some embodiments, conductive materials of metal lines 116 and/or vias 118 of guard ring 140 are the same as conductive materials of metal lines 116 and/or vias 118, respectively, of the interconnect layers of MLI feature 110.

Semiconductor structure 100 may be attached (bonded) to another semiconductor structure to form an IC package or portion thereof. For example, in FIG. 8, semiconductor structure 100 is attached to a semiconductor structure 180, which may be similar to semiconductor structure 100. For example, semiconductor structure 180 includes a respective device substrate 102, a respective MLI feature 110 (having respective dielectric layer 115, respective metal lines 116, and respective vias 118) disposed over side 104 of the respective device substrate 102, and a respective TC layer (having respective contacts 122) disposed over the respective MLI feature 110. In such embodiments, side 106 (e.g., backside) of device substrate 102 of semiconductor structure 100 is attached dielectric layer 115 of semiconductor structure 180, and TSV 130 of semiconductor structure 100 is connected to a respective contact 122 of TC layer of semiconductor structure 180. TSV 130 electrically and/or physically connects semiconductor structure 100 and semiconductor structure 180. In some embodiments, TSV 130 extends through a portion of dielectric layer 115 of semiconductor structure 180 to contact 122 of TC layer of semiconductor structure 180. Semiconductor structure 100 and semiconductor structure 180 may be attached by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or combinations thereof.

In some embodiments, semiconductor structure 100 and semiconductor structure 180 are chips that include at least one functional IC, such as an IC configured to perform a logic function, a memory function, a digital function, an analog function, a mixed signal function, a radio frequency (RF) function, an input/output (I/O) function, a communications function, a power management function, other function, or combinations thereof. In such embodiments, TSV 130 vertically physically and/or electrically connects chips. In some embodiments, semiconductor structure 100 and semiconductor structure 180 are chips that provide the same function (e.g., central processing unit (CPU)). In some embodiments, semiconductor structure 100 and semiconductor structure 180 are chips that provide different functions (e.g., CPU and graphics processing unit (GPU), respectively). In some embodiments, semiconductor structure 100 and/or semiconductor structure 180 is a system-on-chip (SoC), which generally refers to a single chip or monolithic die having multiple functions. In such embodiments, TSV 130 vertically physically and/or electrically connects SoCs. In some embodiments, the SoC is a single chip having an entire system, such as a computer system, fabricated thereon.

In some embodiments, semiconductor structure 100 is a portion of a chip-on-wafer-on-substrate (CoWoS) package, an integrated-fan-out (InFO) package, a system on integrated chip (SoIC) package, other three-dimensional integrated circuit (3DIC) package, or a hybrid package that implements a combination of multichip packaging technologies. In some embodiments, TSV 130 of semiconductor structure 100 is physically and/or electrically connected to a package substrate, an interposer, a redistribution layer (RDL), a printed circuit board (PCB), a printed wiring board, other packaging structure and/or substrate, or combinations thereof. In some embodiments, TSV 130 of semiconductor structure 100 is physically and/or electrically connected to controlled collapse chip connections (C4 bonds) (e.g., solder bumps and/or solder balls) and/or microbumps (also referred to as microbonds, μbumps, and/or μbonds), which are physically and/or electrically connected to a packaging structure.

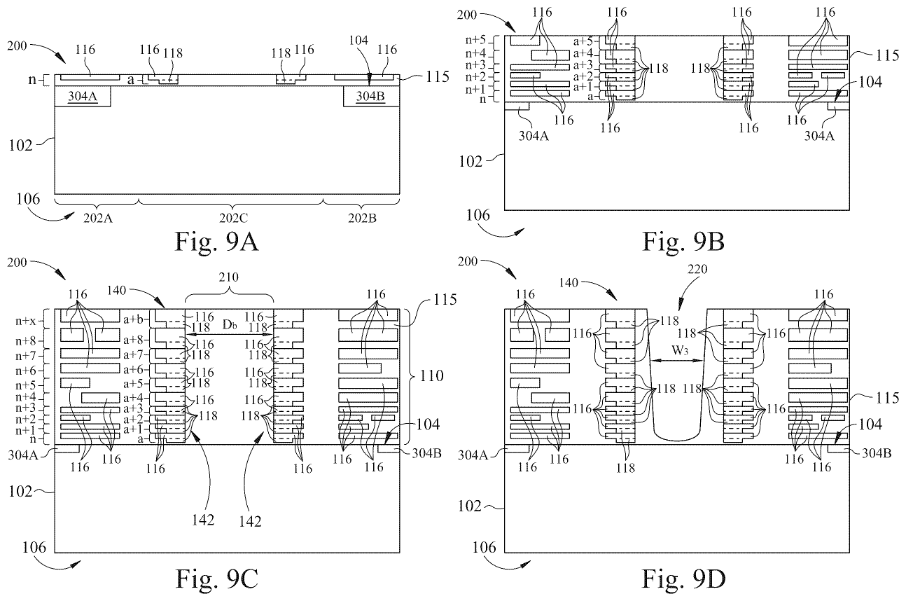

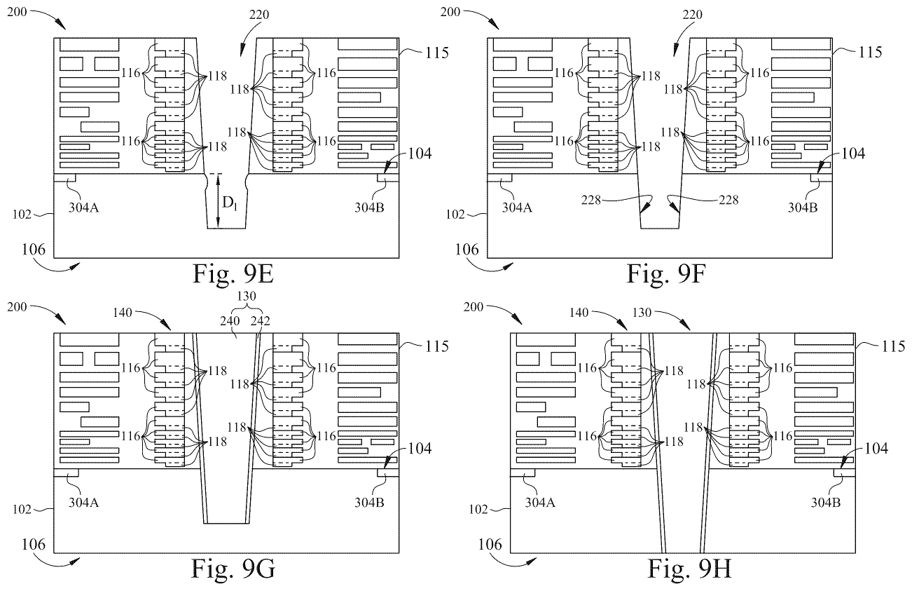

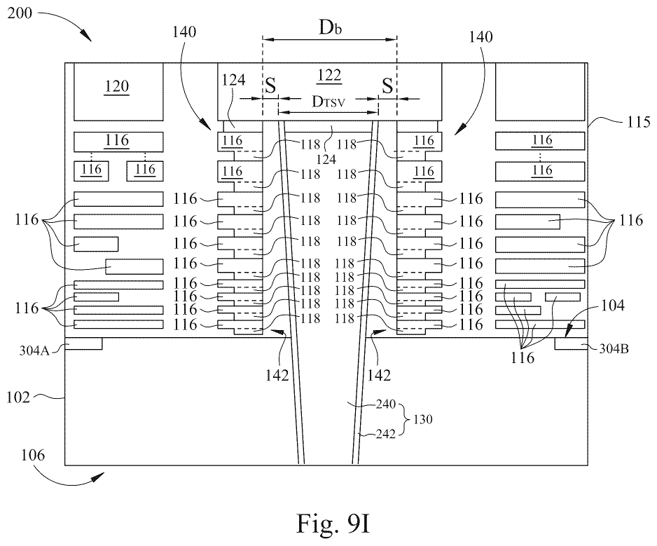

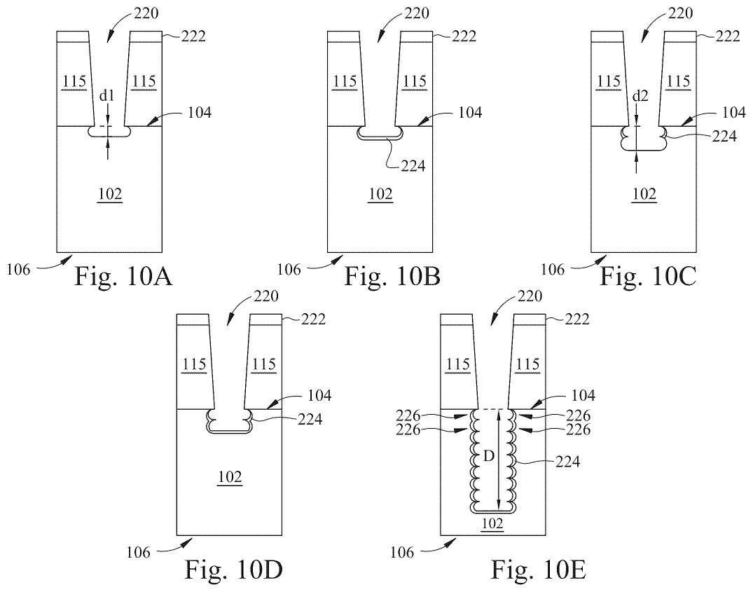

FIGS. 9A-9I are fragmentary cross-sectional views of a workpiece 200, in portion or entirety, at various fabrication stages of forming a guard ring and a TSV according to various aspects of the present disclosure. FIGS. 10A-10E are fragmentary cross-sectional views of a portion of workpiece 200 at various fabrication stages of forming a TSV trench, which can be implemented at the fabrication stage associated with FIG. 9E, according to various aspects of the present disclosure. For ease of description and understanding, the following discussion of FIGS. 9A-9I and FIGS. 10A-10E is directed to fabricating device structure 150 of FIG. 1, which includes TSV 130 and guard ring 140. However, the present disclosure contemplates embodiments where processing associated with FIGS. 9A-9I and/or FIGS. 10A-10E are implemented to fabricate workpieces having different configurations of TSV 130 and/or guard ring 140, such as those described herein. FIGS. 9A-9I and FIGS. 10A-10E have been simplified for the sake of clarity to better understand the inventive concepts of the present disclosure. Additional features can be added in workpiece 200, and some of the features described below can be replaced, modified, or eliminated in other embodiments of workpiece 200.

Turning to FIGS. 9A-9C, after workpiece 200 has undergone FEOL processing and MEOL processing, workpiece 200 undergoes BEOL processing to form MLI feature 110 over a device region 202A and/or a device region 202B of device substrate 102. MLI feature 110 may be physically and/or electrically connected to a device, such as a transistor, formed in device region 202A and/or device region 202B. Guard ring 140 is formed over an intermediate region 202C of device substrate 102 while forming MLI feature 110. Guard ring 140 may be physically and/or electrically connected to a doped region, such as an n-well or a p-well, formed in device substrate 102 in intermediate region 202C. Guard ring 140 is a conductive ring (e.g., a metal ring) having an inner dimension D_{b} that defines a dielectric region 210 of dielectric layer 115. As described further below, TSV 130 is formed to extend through dielectric region 210.

BEOL overlap control, such as described herein, is implemented to ensure that any overlap between vertically stacked conductive layers (or levels) is less than about 10 nm. BEOL overlap control may also be implemented to optimize inner dimension D_{b}. For example, parameters of patterning processes described herein, such as those implemented to form guard ring 140 and/or MLI feature 110, are tuned to ensure overlap between openings in patterned overlying layers and conductive features in patterned underlying layers is less than about 10 nm. In some embodiments, maintaining overlap less than about 10 nm can improve uniformity of inner dimension D_{b} along height H of guard ring 140. In some embodiments, maintaining overlap less than about 10 nm can improve uniformity of spacing S between guard ring 140 and subsequently formed TSV 130. In some embodiments, BEOL control and maintaining overlap less than about 10 nm improves process control of inner dimension D_{b} and/or spacing S, which can reduce process defects during TSV trench formation (FIGS. 9D-9F).

In FIG. 9A, 1st level interconnect layer of MLI feature 110 (i.e., V₁ layer and M₁ layer) and 1^{st} interconnect structure of guard ring 140 (e.g., a interconnect structure) is formed over device substrate 102. For example, a patterned via layer (i.e., vias 118) is formed over device substrate 102 and a patterned metal layer (i.e., metal lines 116) is formed over the patterned via layer. In some embodiments, the patterned via layer is formed by depositing a portion of dielectric layer 115 over an MEOL layer, performing a lithography and etching process to form openings in the portion of the dielectric layer 115 that expose underlying conductive features (e.g., contacts and/or vias of the MEOL layer or device features, such as gates and/or source/drains), filling the openings with a conductive material, and performing a planarization process that removes excess conductive material, where the remaining conductive material that fills the openings provides vias 118. Vias 118 and the portion of dielectric layer 115 may form a substantially planar, common surface after the planarization process. In some embodiments, the patterned metal layer is formed by depositing a portion of dielectric layer 115 over the patterned via layer, performing a lithography and etching process to form openings in the portion of the dielectric layer 115 that expose underlying conductive features (e.g., vias 118 of 1^{st} level interconnect layer and vias of 1^{st} interconnect structure), filling the openings with a conductive material, and performing a planarization process that removes excess conductive material, where the remaining conductive material that fills the openings provides metal lines 116. Metal lines 116 and the portion of dielectric layer 115 may form a substantially planar, common surface after the planarization process. In some embodiments, vias 118 and metal lines 116 are formed by respective single damascene processes (i.e., vias 118 are formed separately from their corresponding overlying and/or underlying metal lines 116).

In some embodiments, depositing the portion of dielectric layer 115 includes depositing an ILD layer. In some embodiments, depositing the portion of dielectric layer 115 includes depositing a CESL. Dielectric layer 115, CESL, ILD layer, or combinations thereof are formed by chemical vapor deposition (CVD), plasma enhanced CVD (PECVD), high density plasma CVD (HDPCVD), flowable CVD (FCVD), physical vapor deposition (PVD), atomic layer deposition (ALD), metalorganic chemical vapor deposition (MOCVD), remote plasma CVD (RPCVD), low-pressure CVD (LPCVD), atomic layer CVD (ALCVD), atmospheric pressure CVD (APCVD), other suitable deposition methods, or combinations thereof.

In some embodiments, 1st level interconnect layer of MLI feature 110 and/or 1^{st} interconnect structure of guard ring 140 are formed by a dual damascene process, which can involve depositing conductive material for via/metal line pairs at the same time. In such embodiments, vias 118 and metal lines 116 may share a barrier layer and a conductive plug, instead of each having a respective and distinct barrier layer and conductive plug (e.g., where a barrier layer of a respective metal line 116 separates a conductive plug of the respective metal line 116 from a conductive plug of its corresponding, respective via 118). In some embodiments, the dual damascene process includes performing a patterning process to form interconnect openings that extend through dielectric layer 115 to expose underlying conductive features. The patterning process can include a first lithography step and a first etch step to form trench openings of the interconnect openings (which correspond with and define metal lines 116) in dielectric layer 115 and a second lithography step and a second etch step to form via openings of the interconnect openings (which correspond with and define vias 118) in dielectric layer 115. The first lithography/first etch step and the second lithography/second etch step can be performed in any order (e.g., trench first via last or via first trench last). The first etch step and the second etch step are each configured to selectively remove dielectric layer 115 with respect to a patterned mask layer. The first etch step and the second etch step may be a dry etching process, a wet etching process, other suitable etching process, or combinations thereof.

After performing the patterning process, the dual damascene process can include performing a first deposition process to form a barrier material over dielectric layer 115 that partially fills the interconnect openings and performing a second deposition process to form a bulk conductive material over the barrier material, where the bulk conductive material fills remainders of the interconnect openings. In such embodiments, the barrier material and the bulk conductive material are disposed in the interconnect openings and over a top surface of dielectric layer 115. The first deposition process and the second deposition process can include CVD, PVD, ALD, HDPCVD, MOCVD, RPCVD, PECVD, LPCVD, ALCVD, APCVD, PEALD, electroplating, electroless plating, other suitable deposition methods, or combinations thereof. A CMP process and/or other planarization process is then performed to remove excess bulk conductive material and barrier material from over the top surface of dielectric layer 115, resulting in the patterned via layer (e.g., vias 118) and the patterned metal layer (e.g., metal lines 116) of 1st level interconnect layer of MLI feature 110 and corresponding 1^{st} interconnect structure of guard ring 140. The CMP process planarizes top surfaces of dielectric layer 115 and vias 118 and/or metal lines 116. The barrier material and the bulk conductive material may fill the trench openings and the via openings of the interconnect openings without interruption, such that barrier layers and conductive plugs of metal lines 116 and vias 118 may each extend continuously from metal lines 116 to respective vias 118 without interruption.

In FIG. 9B, 2^{nd} level interconnect layer through 6^{th} level interconnect layer of MLI feature 110 (i.e., (n+1) level interconnect layer through (n+5) level interconnect layer) are formed over 1^{st} level interconnect layer. 2^{nd} interconnect structure through 6^{th} interconnect structure of guard ring 140 (i.e., (a+1) interconnect structure through (a+5) interconnect structure) are formed while forming 2^{nd} level interconnect layer through 6^{th} level interconnect layer, respectively. Each of 2^{nd} level interconnect layer through 6^{th} level interconnect layer of MLI feature 110, and 2^{nd} interconnect structure through 6^{th} interconnect structure of guard ring 140 corresponding therewith, may be formed as described above with reference to fabrication of 1^{st} level interconnect layer of MLI feature 110 and 1^{st} interconnect structure of guard ring 140.

In FIG. 9C, 7^{th} level interconnect layer through 10^{th} level interconnect layer of MLI feature 110 (i.e., (n+6) level interconnect layer through (n+x) level interconnect layer) are formed over 6^{th} level interconnect layer. 7^{th} interconnect structure through 10^{th} interconnect structure of guard ring 140 (i.e., (a+6) interconnect structure through (a+b) interconnect structure) are formed while forming 7^{th} level interconnect layer through 10^{th} level interconnect layer, respectively. Each of 7^{th} level interconnect layer through 10^{th} level interconnect layer of MLI feature 110, and 7^{th} interconnect structure through 10^{th} interconnect structure of guard ring 140 corresponding therewith, may be formed as described above with reference to fabrication of 1^{st} level interconnect layer of MLI feature 110 and 1^{st} interconnect structure of guard ring 140.

In some embodiments, for a given level interconnect layer, metal lines 116 and vias 118 of an interconnect structure of guard ring 140 at the given level interconnect layer are formed simultaneously with metal lines 116 and vias 118, respectively, of the given level interconnect layer. For example, openings in dielectric layer 115 for vias 118 of V₁ layer and vias 118 of 1^{st} interconnect structure of guard ring 140 are formed by the same patterning process and the openings are filled with conductive material by the same deposition process. In another example, openings in dielectric layer 115 for metal lines 116 of M₁ layer and metal lines 116 of 1^{st} interconnect structure of guard ring 140 are formed by the same patterning process, and the openings are filled with conductive material by the same deposition process.

In some embodiments, for a given level interconnect layer, metal lines 116 and vias 118 of an interconnect structure of guard ring 140 at the given level interconnect layer are formed at least partially simultaneously with metal lines 116 and vias 118, respectively, of the given level interconnect layer. For example, openings in dielectric layer 115 for vias 118 of V₁ layer and vias 118 of 1^{st} interconnect structure of guard ring 140 are formed by the same patterning process, and the openings are filled with conductive material by different deposition processes. In another example, openings in dielectric layer 115 of metal lines 116 of M₁ layer and metal lines 116 of 1^{st} interconnect structure of guard ring 140 are formed by the same patterning process, and the openings are filled with conductive material by different deposition processes. In another example, openings for vias 118 of V₁ layer and vias 118 of 1^{st} interconnect structure of guard ring 140 are filled with conductive material by the same deposition process, and the openings are formed in dielectric layer 115 by different patterning processes. In another example, openings for metal lines 116 of M₁ layer and metal lines 116 of 1^{st} interconnect structure of guard ring 140 are filled with conductive material by the same deposition process, and the openings are formed in dielectric layer 115 by different patterning processes.

In some embodiments, for a given level interconnect layer, metal lines 116 and vias 118 of an interconnect structure of guard ring 140 at the given level interconnect layer are formed by different processes than metal lines 116 and vias 118, respectively, of the given level interconnect layer. For example, vias 118 of V₁ layer are formed by a first set of processes (e.g., a first patterning process and a first deposition process) and vias 118 of 1^{st} interconnect structure of guard ring 140 are formed by a second set of processes (e.g., a second patterning process and a second deposition process). In another example, metal lines 116 of M₁ layer are formed by a first set of processes (e.g., a first patterning process and a first deposition process) and metal lines 116 of 1^{st} interconnect structure of guard ring 140 are formed by a second set of processes (e.g., a second patterning process and a second deposition process).

In some embodiments, for a given level interconnect layer, metal lines 116 and/or vias 118 of an interconnect structure of guard ring 140 at the given level interconnect layer and metal lines 116 and/or vias 118, respectively, of the given level interconnect layer are formed by the same single damascene process. In some embodiments, for a given level interconnect layer, metal lines 116 and/or vias 118 of an interconnect structure of guard ring 140 at the given level interconnect layer and metal lines 116 and/or vias 118, respectively, of the given level interconnect layer are formed by different single damascene processes. In some embodiments, for a given level interconnect layer, metal lines 116 and vias 118 of an interconnect structure of guard ring 140 at the given level interconnect layer and metal lines 116 and vias 118 of the given level interconnect layer are formed by the same dual damascene process. In some embodiments, for a given level interconnect layer, metal lines 116 and vias 118 of an interconnect structure of guard ring 140 at the given level interconnect layer and metal lines 116 and vias 118 of the given level interconnect layer are formed by different dual damascene processes.

In FIG. 9D, a trench 220 is formed in dielectric region 220 of dielectric layer 115. Trench 220 extends through dielectric layer 115 to expose side 104 of device substrate 102. Trench 220 has a width W₃ along the x-direction that is less than inner dimension D_{B} of guard ring 140. In some embodiments, width W₃ is equal to dimension D_{TSV}. In some embodiments, forming trench 220 includes forming a patterned mask layer having an opening therein that exposes dielectric region 210 of dielectric layer 115 and etching dielectric layer 115 using the patterned mask layer as an etch mask. A width of the opening of the patterned mask layer can be configured to provide a desired spacing between guard ring 140 and subsequently formed TSV 130. For example, the opening in the patterned mask layer is provided with a width that is about equal to a desired width and/or a desired diameter of TSV 130. In some embodiments, a ratio of dimension D_{b} to a width of the opening in the patterned mask layer is substantially the same as a ratio of dimension D_{b} to dimension D_{TSV}. Controlling spacing between guard ring 140 and trench 220 can reduce defects that may arise from extending trench 220 into device substrate 102 (i.e., defects caused by a TSV drilling process). The patterned mask layer may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer is a patterned hard mask layer (e.g., a silicon nitride layer). In some embodiments, the patterned mask layer is a patterned resist layer. The etching may be a dry etching process, a wet etching process, other etching process, or combinations thereof.

In FIG. 9E, trench 220 is extended into device substrate 102 by a suitable process, such as an etching process. Fabricating guard ring 140 and trench 220 in FIGS. 9A-9D with overlap control and spacing control as described herein reduces and/or eliminates process defects that may arise from extending trench 220 into device substrate 102, which improves yield (e.g., more known-good-dies result from the processes disclosed herein). The etching process is a dry etching process, a wet etching process, other etching process, or combinations thereof. In some embodiments, the etching process is a dry etching process, such as an isotropic dry etch (i.e., an etching process that will remove material in more than one direction, such as vertically along the z-direction and laterally along the x-direction). In some embodiments, trench 220 extends entirely through device substrate 102, such as from side 104 to side 106. In the depicted embodiment, trench 220 extends a depth D into device substrate 102.

In some embodiments, a Bosch process, such as depicted in FIGS. 10A-10E, is implemented to extend trench 220 into device substrate 102. A Bosch process generally refers to a high-aspect ratio plasma etching process that involves alternating etch phases and deposition phases, where a cycle includes an etch phase and a deposition phase and the cycle is repeated until trench 220 has desired depth D. For example, the Bosch process can include introducing a first gas (e.g., a fluorine-containing gas, such as SF₆) into a process chamber to etch device substrate 102 (e.g., silicon) and extend trench 220 to a depth d1 in device substrate 102 that is less than depth D (FIG. 10A, an etch phase); stopping the first gas and introducing a second gas (e.g., a fluorine-containing gas, such as C₄F₈) into the process chamber that forms a protective layer 224 over surfaces of device substrate 102 that form trench 220 (FIG. 10B, a deposition phase); stopping the second gas and introducing the first gas into the process chamber to further etch device substrate 102 and extend trench 220 to a depth d2 in device substrate 102 that is less than depth D (FIG. 10C, an etch phase); stopping the first gas and introducing the second gas into the process chamber that forms protective layer 224 (also referred to as a polymer layer or a passivation layer) over exposed surfaces of device substrate 102 that form trench 220 (FIG. 10D, a deposition phase); and repeating cycles of the Bosch process (i.e., etch phase plus polymer deposition phase) until trench 220 extends to depth D in device substrate 102 (FIG. 10E). Each etch phase may remove portions of protective layer 224 that cover surfaces of device substrate 102 that form a bottom of trench 220, but not portions of protective layer 224 that cover surfaces of device substrate 102 that form sidewalls of trench 220. Protective layer 224 can include fluorine and carbon (i.e., a fluorocarbon-based layer). The Bosch process can use a patterned mask layer 222 as an etch mask. In some embodiments, patterned mask layer 222 was formed and used as an etch mask when forming trench 220 in dielectric layer 115 in FIG. 9D.

In FIG. 10E, because the Bosch process laterally etches (as well as vertically etches) device substrate 102 during each etch phase, trench 220 has scalloped sidewalls, wavy sidewalls, rough sidewalls, or combinations thereof in device substrate 102, which are formed by curvilinear segments 226. Rough sidewalls can negatively impact subsequently formed TSV 130. For example, TSV 130 may delaminate from device substrate 102. Accordingly, in FIG. 9F, a smoothing process is performed on sidewalls of trench 220. Parameters of the smoothing process are tuned to remove scalloped sidewalls, wavy sidewalls, rough sidewalls, or combinations thereof of trench 220. For example, trench 220 has substantially linear sidewalls and/or substantially flat sidewalls 228 after the smoothing process. In some embodiments, the smoothing process is an etching process that selectively removes a semiconductor material (e.g., silicon portions of device substrate 102) with minimal (to no) removal of a dielectric material (e.g., dielectric layer 115). The etching process is a dry etching process, a wet etching process, other etching process, or combinations thereof. In some embodiments, the smoothing process also removes protective layer 224 from trench 220. In some embodiments, smoothing process may not be performed and protective layer 224 may be removed by a suitable process, such as an etching process, before proceeding with forming TSV 130. In some embodiments, sidewalls of trench 220 are smoothed and protective layer 224 are removed by separate processes.

In FIG. 9G, fabrication proceeds with forming TSV 130, which fills trench 220. TSV 130 extends through dielectric layer 115 and through device substrate 102 to depth D. TSV 130 includes a conductive plug 240 disposed over a barrier layer 242. In some embodiments, TSV 130 is formed by depositing a barrier material (e.g., TiN or TaN) over workpiece 200 that partially fills trench 220, depositing a bulk conductive material (e.g., Cu) over workpiece 200 that fills a remainder of trench 220, and performing a planarization process (e.g., CMP) to remove excess barrier layer material and excess bulk conductive material from over workpiece 200 (e.g., from over a top surface of dielectric layer 115, top surfaces of metal lines 116 of (n+x) level interconnect layer, and top surfaces of metal lines 116 of (a+b) interconnect structure of guard ring 140). A remainder of barrier material and bulk conductive material that fill trench 220 form barrier layer 242 and conductive plug 240, respectively.

In FIG. 9H, a thinning process is performed on device substrate 102 to expose TSV 130, such that TSV 130 extends entirely through device substrate 102. For example, TSV 130 extends from side 104 (e.g., frontside) to side 106 (e.g., backside) of device substrate 102 after the thinning process. The thinning process reduces a thickness of device substrate 102 along the z-direction. The thinning process is a grinding process, a planarization process (e.g., CMP), an etching process, other suitable process, or combinations thereof. The thinning process is applied to side 106 of device substrate 102. In some embodiments, workpiece 200 is attached to carrier wafer (substrate) before performing the thinning process. For example, dielectric layer 115 and/or topmost patterned metal layer (e.g., metal lines 116) may be bonded to a carrier wafer.

In FIG. 9I, fabrication proceeds with forming TC layer over MLI feature 110, TSV 130, and guard ring 140. In some embodiments, forming TC layer includes depositing a passivation layer over workpiece 200 and patterning the passivation layer to have openings therein that expose metal lines 116 of (n+x) level interconnect layer of MLI feature 110, TSV 130, and metal lines 116 of (a+b) interconnect structure of guard ring 140 (i.e., topmost metal features). One of the openings in the patterned passivation layer may expose TSV 130, guard ring 140, and dielectric layer 115 between TSV 130 and guard ring 140. In some embodiments, forming TC layer can further includes depositing conductive material over workpiece 200 that fills the openings in the patterned passivation layer and performing a planarization process that removes excess conductive material from over a top surface of the passivation layer, thereby forming contacts 120, contact 122, and vias 124 in the passivation layer.

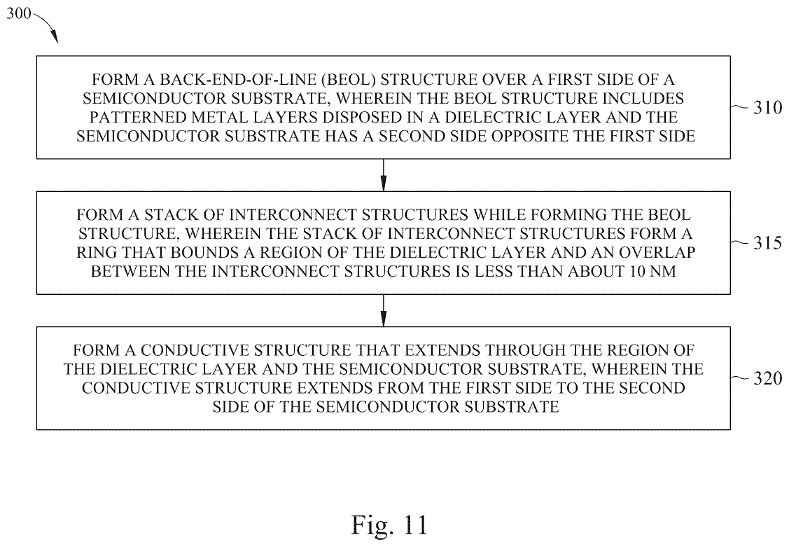

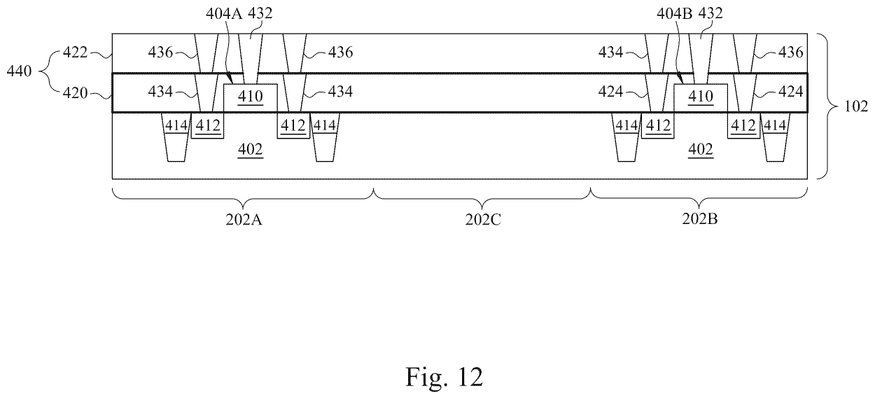

FIG. 11 is a flow chart of a method 300 for fabricating a guard ring and a through via, such as guard ring 140 and TSV 130, according to various aspects of the present disclosure. At block 310, method 300 includes forming a back-end-of-line (BEOL) structure (e.g., MLI feature 110) over a first side of a semiconductor substrate (e.g., side 104 of device substrate 102). The BEOL structure includes patterned metal layers (e.g., n level interconnect layer to (n+x) level interconnect layer) disposed in a dielectric layer (e.g., dielectric layer 115). The semiconductor substrate has a second side opposite the first side (e.g., side 106 of device substrate 102). At block 315, method 300 includes forming a stack of interconnect structures (e.g., a interconnect structure to (a+b) interconnect structure) while forming the BEOL structure. The stack of interconnect structures form a ring (e.g., guard ring 140) that defines a region of the dielectric layer and an overlap between the interconnect structures is less than about 10 nm. In some embodiments, forming the stack of interconnect structures includes performing a patterning process to form an interconnect opening in the dielectric layer and tuning parameters of the patterning process to control a lateral shift of the interconnect opening from an underlying interconnect structure. The lateral shift is less than about 10 nm. At block 320, method 300 includes forming a conductive structure (e.g., TSV 130) that extends through the region of the dielectric layer and the semiconductor substrate. The conductive structure extends from the first side of the semiconductor substrate to the second side of the semiconductor substrate. In some embodiments, the BEOL structure and the semiconductor substrate form a semiconductor structure, which can be attached (bonded) to another semiconductor structure. For example, the second side of the semiconductor substrate is attached to a second semiconductor structure and the conductive structure electrically and/or physically connects the first semiconductor structure and the second semiconductor structure. FIG. 11 has been simplified for the sake of clarity to better understand the inventive concepts of the present disclosure. Additional steps can be provided before, during, and after method 300, and some of the steps described can be moved, replaced, or eliminated for additional embodiments of method 300.

FIG. 12 is a fragmentary diagrammatic cross-sectional view of device substrate 102, in portion or entirety, according to various aspects of the present disclosure. In FIG. 12, device substrate 102 has device region 202A, device region 202B, and intermediate region 202C. Device substrate 102 is depicted with a semiconductor substrate 402 and various transistors, such as a transistor 404A in device region 202A and a transistor 404B in device region 202B. Transistor 404A and transistor 404B each include a respective gate structure 410 (which can include gate spacers disposed along a gate stack (e.g., a gate electrode disposed over a gate dielectric)) disposed between respective source/drains 412 (e.g., epitaxial source/drains), which are disposed on, in, and/or over semiconductor substrate 402, where a channel extends between respective source/drains 412 in semiconductor substrate 402. Device substrate 102 may further include isolation structures 414, such as shallow trench isolation features, that separate and/or electrically isolate transistors, such as transistor 404A and transistor 404B, and/or other devices of device substrate 102 from one another. Device substrate 102 further includes a dielectric layer 420 and a dielectric layer 422, which is similar to and can be fabricated similar to the dielectric layers described herein (i.e., dielectric layer 420 can include one or more ILD layers and/or one or more CESLs). Gate contacts 432 are disposed in dielectric layer 420 and dielectric layer 422, source/drain contacts 434 are disposed in dielectric layer 420, and vias 436 are disposed in dielectric layer 422. Gate contacts 432 electrically and physically connect gate structures 410 (in particular, gate electrodes) to MLI feature 110, and source/drain contacts 434 and/or vias 436 electrically and physically connect source/drains 412 to MLI feature 110. In some embodiments, dielectric layer 420, dielectric layer 422, gate contacts 432, source/drain contacts 434, and vias 436 form an MEOL layer 440. In some embodiments, gate contacts 432, source/drain contacts 434, and/or vias 436 are physically and/or electrically connected to n level interconnect layer of MLI feature 110. In some embodiments, gate contacts 432 and/or vias 436 may form a portion of Vₙ layer of n level interconnect layer, and gate contacts 432 and/or vias 436 are physically and/or electrically connected to Mₙ layer of n level interconnect layer. In some embodiments, dielectric layer 420 and dielectric layer 422 form a portion of dielectric layer 115. In some embodiments, contacts are disposed in dielectric layer 420 over a doped region in semiconductor substrate 402 in intermediate region 202C, and vias are disposed in dielectric layer 422 over the contacts. Such contacts may be physically and/or electrically connected to the doped region, and such vias may be vias 118 of a interconnect structure of guard ring 140 and disposed in Vₙ layer of n level interconnect layer. In such embodiments FIG. 12 has been simplified for the sake of clarity to better understand the inventive concepts of the present disclosure. Additional features can be added in device substrate 102, and some of the features described below can be replaced, modified, or eliminated in other embodiments of device substrate 102.

The present disclosure provides for many different embodiments. An exemplary semiconductor structure includes a device substrate having a first side and a second side. A dielectric layer is disposed over the first side of the device substrate. A through via extends along a first direction through the dielectric layer and through the device substrate from the first side to the second side. A guard ring is disposed in the dielectric layer and around the through via. The guard ring includes metal layers stacked along the first direction. The metal layers include first sidewalls and second sidewall. The first sidewalls form an inner sidewall of the guard ring. An overlap between the first sidewalls of the metal layers is less than about 10 nm. The overlap is along a second direction different than the first direction. In some embodiments, a region defined by the inner sidewall of the guard ring has a first dimension along the second direction, the through via has a second dimension along the second direction, and a ratio of the first dimension to the second dimension is greater than zero and less than about two. In some embodiments, a spacing is between the through via and the inner sidewall of the guard ring, the spacing is along the second direction, and the spacing is about 20 nm to about 50 nm. In some embodiments, the inner sidewall is substantially vertical along the first direction.

In some embodiments, a first set of the metal layers has a first overlap, a second set of the metal layers has a second overlap different than the first overlap, and the first overlap and the second overlap are each less than about 10 nm. In some embodiments, the first set of the metal layers is between the second set of the metal layers and the first side of the device substrate, and the first overlap is less than the second overlap. In some embodiments, a third set of the metal layers has a third overlap that is different than the first overlap and the second overlap, the second set of the metal layers is between the third set of the metal layers and the first set of the metal layers, and the third overlap is greater than the second overlap.

In some embodiments, the semiconductor structure further includes a multilayer interconnect structure disposed in the dielectric layer. The multilayer interconnect structure includes a first set of metallization layers having a first pitch and a second set of metallization layers having a second pitch that is different than the first pitch. The first set of the metal layers are a portion of the first set of metallization layers and the second set of the metal layers are a portion of the second set of metallization layers. In some embodiments, the first set of metallization layers is between the second set of metallization layers and the first side of the device substrate, and the first pitch is less than the second pitch.

An exemplary semiconductor arrangement includes a first semiconductor structure, a second semiconductor structure, and a conductive structure that extends through the first semiconductor structure to the second semiconductor structure. The conductive structure connects the first semiconductor structure and the second semiconductor structure. The semiconductor arrangement further includes a stack of interconnect structures that form a ring around the conductive structure. An overlap between the interconnect structures is less than about 10 nm. In some embodiments, the ring has an inner diameter, the conductive structure has a diameter, and a ratio of the inner diameter to the diameter is greater than zero and less than about two. In some embodiments, the overlap between the interconnect structures increases along a height of the stack of interconnect structures.

In some embodiments, the first semiconductor structure includes a first multilayer interconnect (MLI) feature over a first device substrate and a first top contact layer over the first MLI feature. In some embodiments, the second semiconductor structure includes a second MLI feature over a second device substrate and a second top contact layer over the second MLI feature. In some embodiments, the stack of interconnect structures is disposed in the first MLI feature and the conductive structure extends through the first MLI feature and the first device substrate to the second top contact layer. In some embodiments, the first MLI feature includes metallization layers disposed in a dielectric layer and a number of interconnect structures in the stack of interconnect structures is equal to a number of metallization layers of the first MLI feature. In some embodiments, the first MLI feature includes metallization layers disposed in a dielectric layer and a number of interconnect structures in the stack of interconnect structures is different than a number of metallization layers of the first MLI feature.

In some embodiments, the stack of interconnect structures includes a first interconnect structure disposed directly on a second interconnect structure. The first interconnect structure includes a first metal line disposed over a first via and the second interconnect structure includes a second metal line disposed over a second via. The overlap is between the first metal line and the second metal line. In some embodiments, the first metal line and the second metal line each have a first sidewall and a second sidewall. The first sidewall is proximate the conductive structure and the second sidewall is opposite the first sidewall. The overlap is between the first sidewall of the first metal line and the first sidewall of the second metal line. In some embodiments, the first sidewall of the first metal line is vertically aligned with the first sidewall of the second metal line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a back-end-of-line (BEOL) structure over a first side of a semiconductor substrate, wherein the BEOL structure includes patterned metal layers disposed in a dielectric layer and the semiconductor substrate has a second side opposite the first side;
forming a stack of interconnect structures while forming the BEOL structure, wherein the stack of interconnect structures form a ring that defines a region of the dielectric layer and an overlap between the interconnect structures is less than about 10 nm; and
forming a conductive structure that extends through the region of the dielectric layer and the semiconductor substrate, wherein the conductive structure extends from the first side of the semiconductor substrate to the second side of the semiconductor substrate.

2. The method of claim 1, wherein the forming the stack of interconnect structures while forming the BEOL structure includes performing a patterning process to form an interconnect opening in the dielectric layer and tuning parameters of the patterning process to control a lateral shift of the interconnect opening from an underlying interconnect structure, wherein the lateral shift is less than about 10 nm.

3. The method of claim 1, wherein the forming the stack of interconnect structures while forming the BEOL structure includes forming a first group of interconnect structures and a second group of interconnect structures, the method further comprising:
assigning the first group of interconnect structures a first overlay tolerance and the second group of interconnect structures a second overlay tolerance, wherein the second overlay tolerance is different than the first overlay tolerance; and
the forming the first group of interconnect structures includes patterning the dielectric layer based on the first overlay tolerance and the forming the second group of interconnect structures includes patterning the dielectric layer based on the second overlay tolerance.

4. The method of claim 3, wherein:
the first group of interconnect structures is stacked between the semiconductor substrate and the second group of interconnect structures; and
the first overlay tolerance is less than the second overlay tolerance.

5. The method of claim 3, wherein:
the first group of interconnect structures corresponds with a first group of the patterned metal layers of the BEOL structure, wherein the first group of the patterned metal layers of the BEOL structure have a first pitch; and
the second group of interconnect structures corresponds with a second group of the patterned metal layers of the BEOL structure, wherein the second group of the patterned metal layers of the BEOL structure have a second pitch different than the first pitch.

6. The method of claim 5, wherein the first pitch is less than the second pitch and the first overlay tolerance is less than the second overlay tolerance.

7. The method of claim 1, wherein the forming the stack of interconnect structures while forming the BEOL structure includes forming a first group of interconnect structures and a second group of interconnect structures, wherein the first group of interconnect structures includes first metal lines having a first width and the second group of interconnect structures includes second metal lines having a second width different than the first width.

8. The method of claim 1, wherein:
the ring that defines the region in the dielectric layer has a first diameter;
the conductive structure has a second diameter; and
the forming the stack of interconnect structures and the forming the conductive structure are configured to provide a ratio of the first diameter to the second diameter that is greater than zero and less than about two.

9. The method of claim 1, wherein the forming the conductive structure includes removing a first portion of the dielectric layer in the region in the dielectric layer, wherein a remaining, second portion of the dielectric layer in the region of the dielectric layer provides a spacing between the conductive structure and the ring formed by the stack of interconnect structures, wherein the spacing is about 20 nm to about 50 nm.

10. A method comprising:
forming a conductive structure that extends through a first semiconductor structure to a second semiconductor structure, wherein the conductive structure connects the first semiconductor structure and the second semiconductor structure; and
forming a stack of interconnect structures of the first semiconductor structure before forming the conductive structure, wherein the stack of interconnect structures form a ring around the conductive structure, an overlap between the interconnect structures is less than about 10 nm, the overlap is a distance one group of the interconnect structures is shifted laterally relative to another group of the interconnect structures, and the overlap between the interconnect structures increases along a height of the stack of interconnect structures.

11. The method of claim 10, further comprising:
forming a first multilayer interconnect (MLI) feature of the first semiconductor structure over a first device substrate of the first semiconductor structure and a first top contact layer of the first semiconductor structure over the first MLI feature, wherein the stack of interconnect structures is disposed in the first MLI feature;
forming a second MLI feature of the second semiconductor structure over a second device substrate of the second semiconductor structure and a second top contact layer of the second semiconductor structure over the second MLI feature; and
forming the conductive structure through the first MLI feature and the first device substrate, wherein the conductive structure extends through the first MLI feature and the first device substrate to the second top contact layer of the second semiconductor structure.

12. The method of claim 11, wherein the forming the first MLI feature includes forming metallization layers in a dielectric layer, wherein the stack of interconnect structures is formed to include a number of interconnect structures that is equal to a number of metallization layers of the first MLI feature.

13. The method of claim 11, wherein the forming the first MLI feature includes forming metallization layers in a dielectric layer, wherein the stack of interconnect structures is formed to include a number of interconnect structures that is different than a number of metallization layers of the first MLI feature.

14. The method of claim 10, wherein the ring has an inner diameter, the conductive structure has a diameter, and the method further includes configuring the stack of interconnect structures and the conductive structure to provide a ratio of the inner diameter to the diameter that is greater than zero and less than about two.

15. The method of claim 10, wherein the forming the stack of interconnect structures includes forming a first group of interconnect structures having a first overlap, a second group of interconnect structures having a second overlap disposed over the first group of interconnect structures, and a third group of interconnect structures having a third overlap disposed over the second group of interconnect structures, wherein:
the third overlap is greater than the second overlap;
the second overlap is greater than the first overlap; and
each of the first overlap, the second overlap, and third overlap is less than about 10 nm.

16. The method of claim 10, wherein:
the forming the stack of interconnect structures includes forming a first interconnect structure directly on a second interconnect structure, wherein the forming the first interconnect structure includes forming a first metal line over a first via and the forming the second interconnect structure includes forming a second metal line over a second via; and
the overlap is between the first metal line and the second metal line.

17. The method of claim 10, further comprising attaching the first semiconductor structure and the second semiconductor structure after forming the conductive structure.

18. The method of claim 10, wherein the forming the stack of interconnect structures includes forming a stack of copper-comprising interconnect structures.

19. A device structure comprising:
a device substrate having a first side and a second side;
a dielectric layer disposed over the first side of the device substrate;
a through via that extends along a first direction through the dielectric layer and through the device substrate from the first side to the second side; and
a guard ring disposed in the dielectric layer, around the through via, and spaced away from the through via along a second direction different than the first direction, wherein:
the guard ring includes metal layers stacked along the first direction,
the metal layers include first sidewalls and second sidewalls, wherein the first sidewalls form an inner sidewall of the guard ring, and
a first set of the metal layers has a first overlap between the first sidewalls thereof, a second set of the metal layers has a second overlap between the first sidewalls thereof, the first overlap and the second overlap are along the second direction, the second overlap is different than the first overlap, and the first overlap and the second overlap are each less than about 10 nm.

20. The device structure of claim 19, wherein the first set of the metal layers is between the second set of the metal layers and the first side of the device substrate, and the first overlap is less than the second overlap.
